(19) United States
(12) Patent Application Publication
(10) Pub. No.: US 2024/0157835 A1
(43) Pub. Date: May 16, 2024

(54) A SYSTEM AND A METHOD FOR IN-SITU CONTROLLING AND MONITORING INDIVIDUAL BATTERY CELLS IN A BATTERY SYSTEM

(71) Applicant: Nerve Smart Systems ApS, Roskilde (DK)

(72) Inventors: Karsten Vilstrup Holsted MOGENSEN, Skælskør (DK); Gunnar ROHDE, Rødovre (DK)

(21) Appl. No.: 18/552,006

(22) PCT Filed: Mar. 24, 2022
(86) PCT No.: PCT/DK2022/050058

§ 371 Date: Sep. 22, 2023

(30) Foreign Application Priority Data
Mar. 25, 2021 (DK) PA 2021 70137

(51) Int. Cl. B60L 53/62; B60L 53/53; H01M 10/42; H01M 10/44; H01M 10/46; H02J 7/00

(52) U.S. Cl. CPC B60L 53/62; B60L 53/53; H01M 10/425; H01M 10/441; H01M 10/443; H01M 10/46; H02J 7/0013; H02J 7/0047; H02J 7/0063; H01M 2010/4271; H01M 2220/20

(57) ABSTRACT

A method for controlling and monitoring individual battery cells (3) in a battery system (1), the method comprising the steps of providing (101) a battery system (1) comprising a plurality of battery cells and electrical circuitry (4), the electrical circuitry (4) being configured to enable each single battery cell (3) of the plurality of battery cells to be bypassed individually, providing (102) a battery management system (2), connecting (103) the battery system (1), the electrical circuitry (4) and the battery management system (2) in such a way that the battery management system (2) is enabled to, in operation, selectively control the electrical circuitry (4) to bypass one or more single battery cells (3) of the plurality of battery cells individually, determining (104), using the battery management system (2), whether a battery cell (3) of the plurality of battery cells is bypassed, and, if a battery cell (3) is determined to be bypassed, determining (105-108), using the battery management system (2), open-circuit voltage characteristics of the bypassed battery cell (3).

### TECHNICAL FIELD

The present invention relates to a method for controlling and monitoring, in-situ or in a test environment, individual battery cells in a battery system, such as a battery system for a charging station for electrical vehicles. The present invention further relates to system for controlling and monitoring, in-situ or in a test environment, individual battery cells in a battery system, the system comprising a battery system comprising a plurality of battery cells and electrical circuitry, the electrical circuitry being configured to enable each single battery cell of the plurality of battery cells to be bypassed individually, and a battery management system.

The battery system may be a battery system for any feasible application, examples including charging systems or stations for electrically powered vehicles, wind energy systems, solar energy systems, hydro energy systems and many more applications in which battery systems are needed or used.

### BACKGROUND ART

All known (lithium-based) battery cells share a general structure as a combination of two electrochemical half-cells. Since most (lithium-based) battery cells have a single cell nominal voltage below 5 V direct current (DC) most battery packs, battery modules, and battery strings in practical applications need a serial connection of a number of individual battery cells to meet major required nominal battery system voltages between 48 V DC and 1.500 V DC.

Such a battery pack, battery module or battery string may be used in many different applications, such as but not limited to charging stations for electrical vehicles.

Especially lithium-based battery systems need continuous monitoring and supervision of their operating ranges and parameters as illustrated in FIGS. 1 and 2 due to their comparatively high energy density. According to Ohm's voltage law, a safe operation of the complete battery system is thereby dependent of a safe operation of each individual battery cell. That means, in modular and scalable battery systems, every individual battery cell requires monitoring and supervision of its operating ranges and parameters according to FIGS. 1 and 2. Such monitoring and supervision functionalities are typically undertaken by a battery management system (BMS).

The prior art method of choice for (advanced) BMS to describe the electrical behavior of battery cells, packs, battery modules and battery systems is via an appropriate electrical equivalent circuit diagram (EECD). The so-called Helmholtz-Thévenin-Theorem states that any linear electrical circuit with two terminals can be replaced by a single equivalent voltage source together with an equivalent series impedance. This replacement is analytically precise. The single equivalent impedance in series, however, may be of arbitrary complexity and non-irreducible.

Most (lithium-based) battery cells can be interpreted as two-terminal electrical circuits with an appropriate EECD. The equivalent voltage source is given by the open-circuit voltage (OCV) characteristics which again is a function of some battery parameters like the state of charge (SoC), the state of health (SoH) and the operating temperature. The equivalent series impedance shown in FIG. 5 is an example and consists of several different components.

The challenge in exploiting EECDs to accurately describe (lithium-based) batteries is to estimate the electrical parameters for the equivalent circuits. With typical battery systems in practical applications, the first challenge is to estimate parameters for the EECDs of several hundreds of battery cells. Even if of the same type, the electrical parameters of the individual battery cells may vary due to tolerances in raw materials, production, and/or assembly. Over time and in use (lithium-based) batteries typically degrade with respect to useable capacity and/or power. This results in continuous changes of the electrical parameters in their equivalent circuit. Therefore, these parameters do not only need to be estimated accurately, they also must be tracked during operation.

The current state of knowledge to exploit EECDs for the model-based control and management of (lithium-based) batteries and the experimental investigations are multifaceted. Most of them are based on one or more of the following approaches.

First of all, in most practical applications the general EECD as shown in FIG. 3 is significantly reduced in complexity as a trade-off between required accuracy in the description of battery cells and the necessary effort to estimate the parameters for the equivalent diagram. Among the widely used reductions of a battery equivalent circuit are:
To keep the whole methodology with modelling a (lithium-based) battery by an EECD alive, the Warburg impedance is for practical reasons typically modelled by one or two RC-circuits in series connection.
Both the double-layer capacity C_{dl} and the charge-transfer resistance R_{ct} are often completely neglected with the reason that these parameters are only significant under operating conditions that are not relevant for practical applications.
The hysteresis term is often simply reduced by a lookup table with measured values, or may even be entirely neglected, with the argument that hysteresis effects are indirectly fitted into the other EECD parameters.

With these assumptions, a practical equivalent EECD of (lithium-based) battery cells in practical applications may be determined. An example of such an EECD is shown in FIG. 4.

Next, the parameters in (lithium-based) battery equivalent circuits are estimated by experimental investigations according to a specific procedure, such as for example the following.
The open-circuit voltage characteristics as equivalent voltage source of a (lithium-based) battery cell is directly measured in form of a complete charge/discharge curve at very low current rates (typically between 1/25 and 1/30 C1-rate, where the Cn-rate defines the amount of load current (in Ampere) that is required to charge or discharge a battery with a capacity of x Ah in 1 hour).
The values of the series resistance, Rₛ, are typically obtained from high-current charge/discharge pulses at partial state of charge (pSoC) and then fitting methods (e.g. linear regression) are used to approximate the slope of Rₛ.
The parameter of the two RC-circuits of the Warburg impedance are normally extracted by mathematical methods from an alternating current (AC) electrochemical impedance spectrum (EIS), typically between 100 kHz and 10 Hz.

Many additional and different test procedures exist and are used today. Most of them are used on a statistically optimal number of individual battery cells. Average values from these measurements are then used as parameter values for all the individual cells in large battery systems. To reflect changes (decreases and increases) of the parameter values over lifetime of a battery system, the individual cells are typically equipped with (averaged) degradation factors.

A first disadvantage with the current state of the art is that EECDs used to describe the behavior of batteries are simplified as may e.g. be seen by comparing the examples of FIGS. 3 and 4. The equivalent circuits might still be analytically precise, but it can be hard to perform sufficient experiments to generate appropriate measurements to extract parameter values. If, for example, the charge-transfer resistor R_{tc} is removed from such a circuit, it does not mean that a battery cell under experimental investigation will not show any charge-transfer-related resistance characteristics. Depending on the methods used for parameter fitting, it might then happen that (dynamic) charge-transfer characteristics are fitted into (static) electrolyte resistance characteristics. In this case, even a quite precise parameter fitting can lead to not very accurate predictability of a battery cells behavior.

Besides simplification, it is another disadvantage that EECDs are 1-dimensional, hence they do not represent gradients in operating conditions and/or parameter values over the dimensions of battery cells in practical applications. In larger batteries of around 100 Ah capacity the thermal gradient, for example, can lead to up to 10 K of difference between the hottest and the coldest spot of the electrochemical active surface area. In this case, the safety margin in relation to temperature always needs to be adopted with respect to the hottest (coldest) spot. This, however, results in too strict safety borders for most of all the other spots within a battery cell.

The use of averaged values for the parameters of the EECDs for all individual cells in a battery system inevitably leads to that the majority of battery cells is heavily underloaded (in case of very conservative parameters) or that a variety of battery cell is heavily overloaded (in case of moderate parameters). In any case, the battery system cannot exploit its complete performance and is most likely to fail earlier than expected due to single (weak) cells that are permanently overloaded.

Furthermore, such averaged parameter estimations are still coming from measurements under laboratory conditions. Even if these laboratory conditions are properly chosen, they normally do not consider that the different individual cells in a battery system might be exposed to different environmental and/or operating conditions. This might lead to considerably divergent short-term and long-term behavior of the battery cells which is not properly addressed by common (averaged) parameters.

The main disadvantaged client of the current state of knowledge are primarily operators, owners, and users of battery systems; in the short run they get not the most capacity and/or power out of their battery system and in the long run the battery is likely to cause higher total cost of ownership or a shorter lifetime.

### SUMMARY OF INVENTION

It is therefore the object of the invention to provide a method for controlling and monitoring individual battery cells in a battery system with which at least some of the above advantages may be minimized or avoided altogether.

It is a further object of the invention to provide such a method which provides for one or more of:
an improved accuracy in predictability of the behavior of a battery cell,
better exploitation of the safety borders of the individual battery cell in order to avoid too strict safety borders for most of all the other spots within a battery cell,
avoiding heavy overloads or underloads of individual battery cells to allow the battery system to exploit its complete performance and enable the battery system to be less prone to failing earlier than expected due to single (weak) cells that are permanently overloaded,
enabling to take into account that the different individual cells in a battery system might be exposed to different environmental and/or operating conditions, such as to achieve more stable short-term and long-term behavior of the battery cells, and
improved flexibility in use, particularly such as to enable not only measurements under laboratory conditions, but also measurements under use conditions, on the individual battery cells.

The invention is defined by the subject matter of the independent claims. Particular embodiments of the invention are set out in the dependent claims.

These and other objects are in a first aspect of the invention achieved by means of a method for controlling and monitoring individual battery cells in a battery system, the method comprising the steps of providing a battery system comprising a plurality of battery cells and first electrical circuitry, the first electrical circuitry being configured to enable each single battery cell of the plurality of battery cells to be bypassed individually, providing a battery management system comprising second electrical circuitry, connecting the first electrical circuitry and the second electrical circuitry in such a way that the battery management system is enabled to, in operation, selectively control the first electrical circuitry to bypass one or more single battery cells of the plurality of battery cells individually, determining, using the battery management system, whether a battery cell of the plurality of battery cells is bypassed, if a battery cell is determined to be bypassed, measuring, using the battery management system, at least an actual nominal voltage and a temperature of the bypassed battery cell, determining, using the battery management system, at least one further parameter of the bypassed battery cell, determining open-circuit voltage characteristics of the bypassed battery cell based on the measured actual nominal voltage and temperature and the determined at least one further parameter of the bypassed battery cell, and at least one of controlling and monitoring each battery cell within the battery system based on the determined open-circuit voltage characteristics.

The open-circuit voltage characteristics as equivalent voltage source of a (lithium-based) battery cell may be measured directly in form of a complete charge/discharge curve at very low current rates. The open-circuit voltage is the difference of electrical potential between two terminals of a device, here the battery cell, when disconnected from any circuit. No external load is connected and no external electric current flows between the terminals of the battery cell. The open-circuit voltage may also be thought of as the voltage that must be applied to a battery to stop the current.

Thereby, and especially by configuring the electrical circuitry, connecting the second electrical circuitry of the battery management system and the first electrical circuitry of the battery system as described above and by using the battery management system to determine whether a battery cell of the plurality of battery cells is bypassed, and if a battery cell is determined to be bypassed, using the battery management system to determine open-circuit voltage characteristics of the bypassed battery cell as described above, a method is provided with which relevant measurements may be performed on single battery cells in a particularly simple and easy manner.

By thus enabling measurements on single battery cell level, a method is provided with which an improved accuracy in predictability of battery cells behavior, better exploitation of the safety borders of the individual battery cell in order to avoid too strict safety borders for most of all the other spots within a battery cell, avoiding heavy overloads or underloads of individual battery cells to allow the battery system to exploit its complete performance and enable the battery system to be less prone to failing earlier than expected due to single cells that are permanently overloaded, and enabling to take into account that the different individual cells in a battery system might be exposed to different environmental and/or operating conditions, such as to achieve more stable short-term and long-term behavior of the battery cells is obtained. Furthermore, such a method reduces the necessary computer power of the battery management system and, consequently, the cumulative error, of solely model-based parameter estimations.

Furthermore, such a method has an improved flexibility in the sense that it may be used not only in the test laboratory, but also for controlling and monitoring individual battery cells in a battery system in-situ, i.e. at the site where the battery system is installed in an application.

The battery system may in one embodiment be a battery system for a charging station for electrical vehicles.

In an embodiment, the step of connecting the first electrical circuitry and the second electrical circuitry comprises, for each battery cell of the plurality of battery cells, connecting the second electrical circuitry to a first switch of the first electrical circuitry and associated with the battery cell.

Thereby, a particularly simple electrical connection enabling measurements on a single cell level is obtained.

In an embodiment, the step of determining, using the battery management system, whether a battery cell of the plurality of battery cells is bypassed comprises detecting transients in the nominal voltage of the battery cell caused by a switch, particularly the first switch, being opened, and, if transients in the nominal voltage of the battery cell are detected, determining that the battery cell is bypassed.

As it has been shown that such transients are always caused when opening an electrical switch, such a method provides for a particularly simple manner of detecting with a high degree of certainty that a battery cell is bypassed.

In an embodiment, the step of determining, using the battery management system, whether a battery cell of the plurality of battery cells is bypassed comprises detecting whether the first switch is opened, and, if the first switch is opened, determining that the battery cell is bypassed.

Such a method provides for a particularly simple manner of detecting with a high degree of certainty that a battery cell is bypassed.

In an embodiment, further parameters of the bypassed battery cell comprise any one or more of a state of charge (SoH) of the battery cell, a partial state of charge (pSoH) of the battery cell, a state of health (SoH) of the battery cell, a current pulse, an Ohmic electrolyte resistance of the battery cell, a Warburg impedance of the battery cell and an electrochemical impedance spectrum of the battery cell.

These are all parameters providing important information regarding the state of the battery cell to a given point in time. Together with the actual nominal voltage and the temperature, the two most important of these parameters are the Ohmic electrolyte resistance of the battery cell and the electrochemical impedance spectrum of the battery cell. Thus, by determining at least these two further parameters, and optionally one or more of the other further parameters of the battery cell, particularly detailed information regarding the battery cell may be obtained in a simple and straight forward manner.

In an embodiment, the steps of measuring the actual nominal voltage and the temperature of the bypassed battery cell and of determining further parameters of the bypassed battery cell is performed after a predetermined relaxation time following determination of the battery cell having been bypassed has elapsed.

When a battery cell is bypassed, it only assumes a steady state of the battery voltage after a period of time has elapsed after the battery has been bypassed. This period of time is called the relaxation time of the battery. The relaxation time may be in the range of minutes, hours or even days depending on the accuracy needed since the battery cell evolves towards the steady state voltage in an asymptotic manner. By in this way taking into account the relaxation time of the battery cell, the accuracy of the measurements, and especially of the state of charge of the battery cell, are increased due to avoiding error sources stemming from the battery cell voltage not being sufficiently close to a steady state.

In an embodiment, the step of measuring the actual nominal voltage and the temperature of the bypassed battery cell is repeated every time the battery cell is determined bypassed.

Thereby, a method is provided with which the actual nominal voltage and the temperature of any given battery cell are updated as often as possible, and thus always kept up to date, is obtained. This further increases the accuracy of the measurements at a given point of time.

In an embodiment, the step of connecting the first electrical circuitry and the second electrical circuitry comprises, for each battery cell of the plurality of battery cells, connecting the second electrical circuitry to a first switch of the first electrical circuitry and associated with the battery cell and to at least one further switch associated of the first electrical circuitry and with the battery cell.

Thereby, a particularly simple electrical connection enabling measurements on a single cell level is obtained, and a method with which bypassed cells may be detected in a straight forward and certain manner is provided, also for electrical circuitry constructions where the individual battery cells are associated with more than one switch.

In a second aspect of the invention, the above and other objects are achieved by means of a system for controlling and monitoring individual battery cells in a battery system, such as a battery system for a charging station for electrical vehicles, the system comprising a battery system comprising a plurality of battery cells and first electrical circuitry, the first electrical circuitry being configured to enable each single battery cell of the plurality of battery cells to be bypassed individually, and a battery management system comprising second electrical circuitry, the first electrical circuitry and the second electrical circuitry system being connected in such a way that in such a way that the battery management system is enabled to, in operation, selectively control the first electrical circuitry to bypass one or more single battery cells of the plurality of battery cells individually, the battery management system being configured to determine whether a battery cell of the plurality of battery cells is bypassed, and if a battery cell is determined to be bypassed, measure an actual nominal voltage and a temperature of the bypassed battery cell, determine at least one further parameter of the bypassed battery cell, determine open-circuit voltage characteristics of the bypassed battery cell based on the measured actual nominal voltage and temperature and the determined at least one further parameter of the bypassed battery cell, and at least one of controlling and monitoring each battery cell within the battery system based on the measured open-circuit voltage characteristics.

The system may be a system for in-situ controlling and monitoring individual battery cells in a battery system.

In an embodiment of the system, the battery management system further is configured to determine whether a battery cell of the plurality of battery cells is bypassed by:
detecting transients in the nominal voltage of the battery cell caused by the first switch being opened, and, if transients in the nominal voltage of the battery cell are detected, determine that the battery cell is bypassed, or
detecting whether the first switch is opened, and, if the first switch is opened, determine that the battery cell is bypassed,

In some embodiments of the system, the battery management system further is configured to any one or more of:
measure said actual nominal voltage and said temperature, and determine said at least one further parameter, of the bypassed battery cell after a predetermined relaxation time following determination of the battery cell having been bypassed has elapsed, and
measure said actual nominal voltage and said temperature of the bypassed battery cell every time the battery cell is determined bypassed.

In some embodiments of the system, the first electrical circuitry and the second electrical circuitry are connected in such a way that:
for each battery cell of the plurality of battery cells, the second electrical circuitry is connected to a first switch of the first electrical circuitry and associated with the battery cell, or
for each battery cell of the plurality of battery cells, the second electrical circuitry is connected to a first switch of the first electrical circuitry and associated with the battery cell and to at least one further switch of the electrical circuitry and associated with the battery cell.

In addition to achieving the above-mentioned advantages, such embodiments of the electrical connection provide for a system with a particularly simple connection and thus circuitry and construction.

### BRIEF DESCRIPTION OF DRAWINGS

In the following description embodiments of the invention will be described with reference to the schematic drawings, in which

FIGS. 1 and 2 show two diagrams illustrating a qualitative description of safe operating ranges, safety margins, and failure zones of lithium-based secondary batteries with respect to their operating parameters. FIG. 1 shows the magnitude of current of the battery cell as a function of temperature. FIG. 2 shows the voltage of the battery cell as a function of temperature.

FIG. 3 shows an exemplary electrical equivalent circuit diagram (EECD), where the EECD is a general electrical equivalent circuit diagram of a (lithium-based) battery cell, where the dotted lines between the two RC-circuits and the resistor R_{ct} indicate that the analytic equivalent impedance requires an infinite series connection of RC-circuits.

FIG. 4 shows an exemplary EECD being a practical electrical equivalent circuit diagram of a (lithium-based) battery cell, where the two RC-circuits represent the dynamical behavior and the series resistor Rₛ describes the behavior of the battery cell at rest.

FIGS. 5A-5C show circuit diagrams corresponding to a part of a battery system and comprising two battery cells and illustrating schematically how to bypass or to engage a given individual battery cell in an exemplary battery system comprising a plurality of battery cells. FIG. 5A shows a circuit diagram illustrating both battery cells being engaged. FIG. 5B shows a circuit diagram illustrating an intermediate step on the way to bypassing the battery cell denoted Celli. FIG. 5C shows a circuit diagram illustrating battery cell denoted Celli being bypassed.

FIG. 6 shows a circuit diagram illustrating schematically a system for controlling and monitoring individual battery cells in a battery system according to an embodiment of the invention.

FIG. 7 shows a plot of the potential and the current, respectively, of an electrical battery equivalent circuit diagram as a function of time, the plot illustrating how to deduce the Ohmic electrolyte resistance and the total resistance from the voltage response due to a current interruption.

FIG. 8A illustrates the voltage transient in a reconfigurable battery system in the situation when battery cell i of FIG. 6 is bypassed and replaced by battery cell i+1 of FIG. 6. From the top and downwards the four graphs of FIG. 8A illustrate the total voltage, V_{batt}, of the battery assembly, the nominal current, Iᵢ, of battery cell i, the nominal voltage, Vᵢ₊₁, of battery cell i+1, and the nominal voltage, Vᵢ, of battery cell i.

FIG. 8B illustrates the voltage transient in a reconfigurable battery system in the situation when battery cell i+1 of FIG. 6 is bypassed and replaced by battery cell i of FIG. 6. From the top and downwards the four graphs of FIG. 8B illustrate the total voltage, V_{batt}, of the battery assembly, the nominal current, Iᵢ, of battery cell i, the nominal voltage, Vᵢ₊₁, of battery cell i+1, and the nominal voltage, Vᵢ, of battery cell i.

FIG. 9 shows a plot of the imaginary part of the impedance as a function of the real part of the impedance illustrating the an electrochemical impedance spectrum (EIS) and its interpretation in terms of parameters in an electrical equivalent circuit diagram (EECD) of a (lithium-based) battery cell.

FIG. 10 shows a schematic illustration of a method according to an embodiment of the invention.

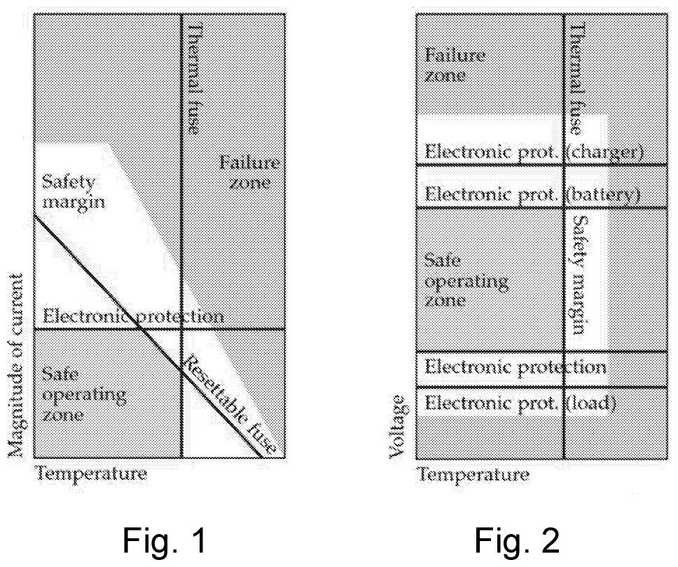

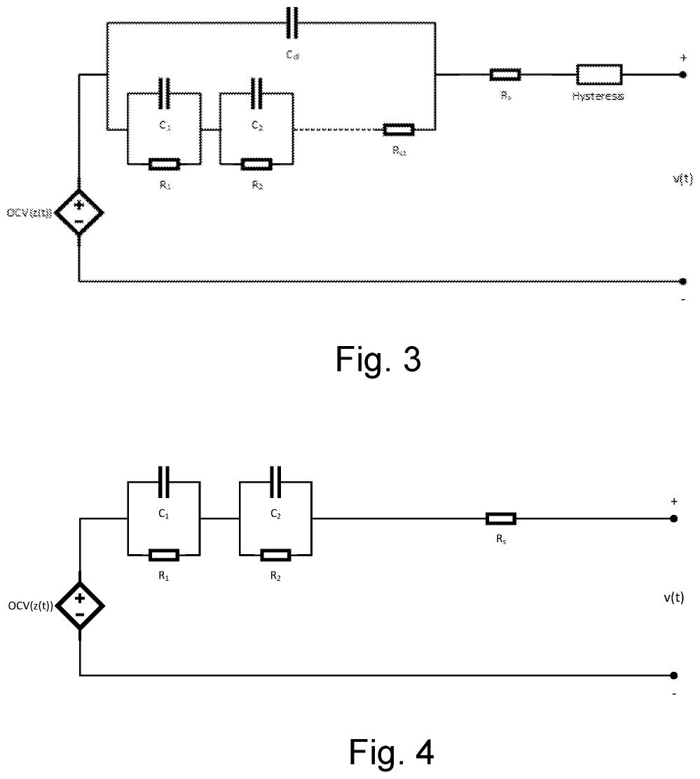

### DESCRIPTION OF EMBODIMENTS

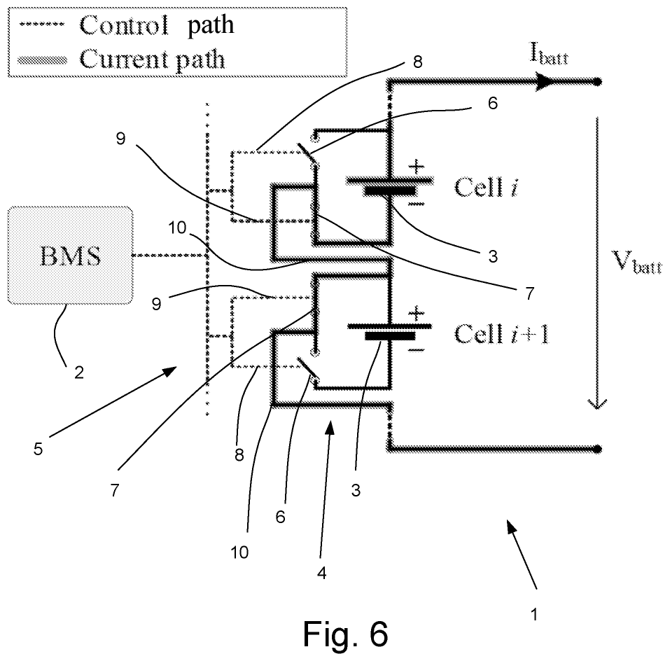

Referring first to FIG. 6, a circuit diagram illustrating a system for controlling and monitoring individual battery cells in a battery system 1 according to the invention is shown. The system according to the invention generally comprises a battery system 1 comprising a plurality of battery cells 3 and first electrical circuitry 4, and a battery management system (BMS) 2 with second electrical circuitry 5.

The circuit diagram of FIG. 6 shows for the sake of simplicity only two neighboring battery cells 3 of the battery system 2. The battery cells are denoted cell i and cell i+1, where i denotes an integer being 1 or more. In other words, the battery system 2 may comprise any number of battery cells 3. One non-limiting example of a suitable battery system 2 is a 100 Ah lithium-iron phosphate battery cell assembly with a plurality of battery cells. In principle, the battery system 2 may also comprise several groups of battery cells, so called battery cell assemblies, connected in parallel.

The battery system 1 may be any feasible type of battery system to be used in applications where battery power is needed to power an appliance and/or to store electrical energy. Generally, the battery system 2 is a reconfigurable battery system with variable topology. For instance, the battery system 1 may be used in a charging station for charging electrical vehicles. The battery system 1 may also be used as the battery system installed in the electrical vehicle itself. The battery system 1 may comprise any feasible number of battery cells 3. The battery cells 3 may thus also be any feasible type of battery cell 3 depending on the application in which the battery system 1 is to be used.

The first electrical circuitry 4 is generally configured to enable each single battery cell 3 of the plurality of battery cells 3 to be bypassed individually. The first electrical circuitry 4 is in the embodiment shown in FIG. 6 shown in full lines. The first electrical circuitry 4 is in the embodiment shown in FIG. 6 configured to connect the battery cells 3 of the battery system 1 in a parallel configuration. The first electrical circuitry 4 may be arranged on a printed circuit board or like substrate. The first electrical circuitry 4 may furthermore provide a connection to external elements, such as components of an application to be powered by the battery system 1.

The battery management system 2 may be any feasible battery management system, such as but not limited to e.g. the applicant's Nerve Switch® battery management system described in the applicant's WO 2018/072799 A1.

The battery system 1 and the battery management system 2 are generally connected in such a way that for each battery cell 3 of the plurality of battery cells 3, the battery management system 2 is connected to a first switch 6 associated with the battery cell. The first switch 6 forms part of the first electrical circuitry 4. To this end the battery management system 2 comprises second electrical circuitry 5 shown with dotted lines in FIG. 6. The second electrical circuitry 5 comprises a first circuit element 8 forming the connection to the first switch 6.

In the embodiment shown in FIG. 6, each battery cell 3 is associated with two switches 6 and 7 arranged on opposite sides of the battery cell 3. The switches 6 and 7 form part of the first electrical circuitry 4. The switch 6 is arranged between the negative terminal (−) of the battery cell 3 and the circuit element 10, i.e. in an inlet line of the battery cell 3. The switch 7 is arranged between the positive terminal (+) of the battery cell 3 and the circuit element 10, i.e. in an outlet line of the battery cell 3. The battery system 1 and the battery management system 2 are therefore furthermore connected in such a way that for each battery cell 3 of the plurality of battery cells 3, the battery management system 2 is connected to a second switch 7 of the battery cell. To this end the second electrical circuitry 5 of the battery management system 2 comprises a second circuit element 9 forming the connection to the second switch 7.

In other embodiments, where only one switch, typically the switch 6, is provided, the battery management system 2 need only be connected to a first switch 6 of or associated with the battery cell 3. In yet other embodiments, where more than two switches, e.g. three or four switches is provided and associated with each battery cell 3, the battery management system 2 may be connected to three or more, but typically all, of such switches depending on the need for controlling the switches.

It is noted that as used herein, the term “switch” is intended to encompass both electronic switches, such as e.g. metal-oxide-semiconductor field-effect transistors (MOSFETs), and mechanical switches.

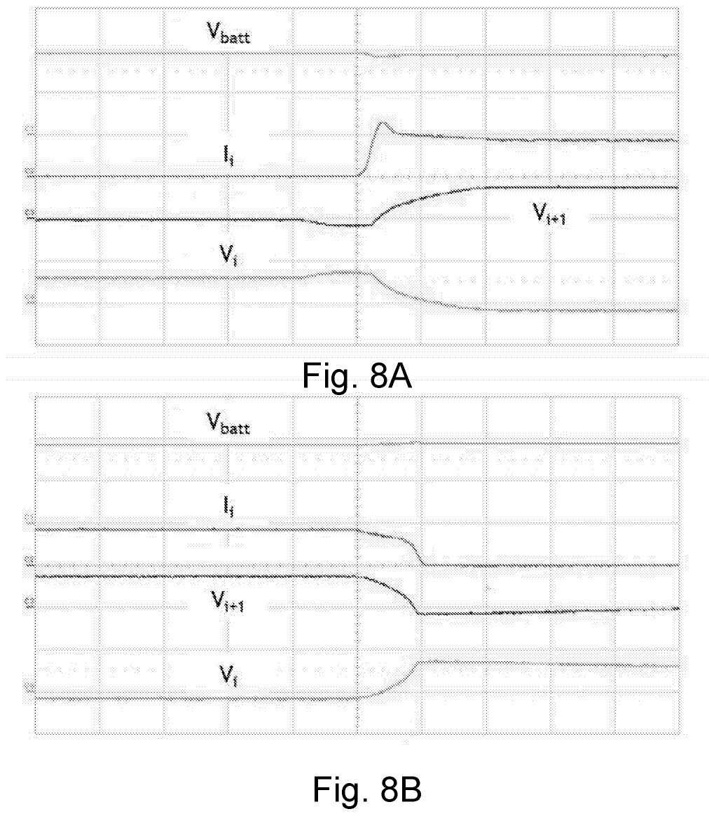

In any event, the battery management system 2 is configured to determine whether a battery cell 3 of the plurality of battery cells 3 is bypassed by detecting transients in the nominal voltage of the battery cell 3. Such transients are illustrated by way of an example in FIGS. 8A and 8B. FIG. 8A illustrates the situation when battery cell i of FIG. 6 is bypassed and replaced by battery cell i+1 of FIG. 6. FIG. 8B illustrates the situation when battery cell i+1 of FIG. 6 is bypassed and replaced by battery cell i of FIG. 6. As may be seen, while the total voltage, V_{batt}, of the battery assembly remains approximately constant before and after a battery cell replacement, clear transients may be seen in both the nominal voltage and the nominal current of each battery cell (cell i and cell i+1) involved in the replacement, and thus being engaged or bypassed.

The battery management system 2 is configured to measure such transients in the nominal voltage of a battery cell 3 in the moment when the battery cell 3 is changing status from engaged to bypassed (and/or vice versa).

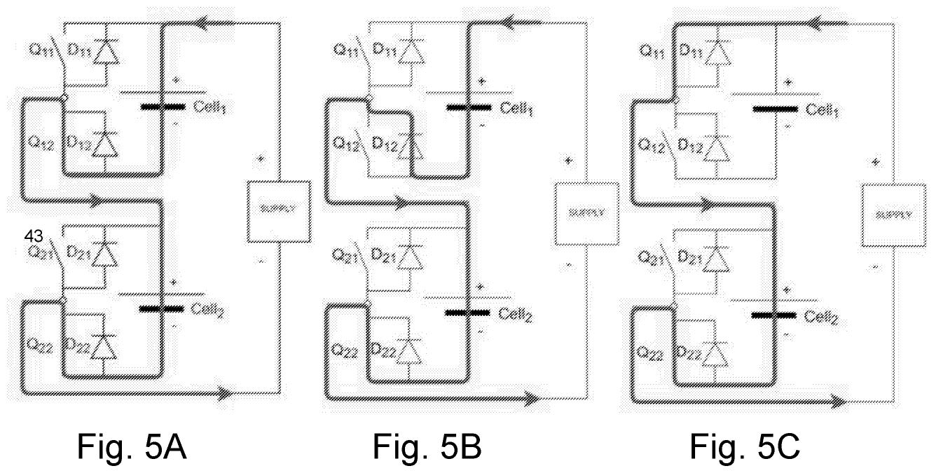

FIGS. 5A-5C show circuit diagrams corresponding to a part of a battery system and comprising two battery cells and illustrating in detail the actual sequence in the situation of switching a battery cell from engaged state to bypassed state during operation. FIGS. 5A-5C shows a circuit in which each battery cell is associated with two switches. In other embodiments of battery systems, each battery cell may be associated with one switch only or with more than two switches.

When both battery cells are engaged for charging (FIG. 5A), the switches Qₓ₂ are closed while the switches Qₓ₁ are open. All current is flowing through the battery cells, and no current is flowing through the bypass diodes Dₓₓ. On a control signal from a battery management system to bypass battery cell Celli, the switch Q₁₂ opens before the switch Q₁₁ closes to avoid short-circuiting the battery cell (FIG. 5B). This operation requires that for a short moment current is allowed to flow through the bypass diode D₁₂ to avoid breaking the current path in the battery system. Finally, the switch Q₁₁ closes and all current is flowing through the bypass circuit around battery cell cell₁ (FIG. 5C). The battery cell cell₁ is bypassed (c). An analogous procedure may be used to bypass the battery cell cell₂. Also, an analogous process may be used to bypass one or more battery cells in a battery system where each battery cell may be associated with one switch only or with more than two switches.

The battery management system 2 is further configured to, if a battery cell is determined to be bypassed, measure open-circuit voltage characteristics of the bypassed battery cell. The battery management system 2 may further be configured to measure said open-circuit voltage characteristics of the bypassed battery cell 3 after a predetermined relaxation time following determination of the battery cell 3 having been bypassed has elapsed. The battery management system 2 may further be configured to repeat the measurement of open-circuit voltage characteristics of the bypassed battery cell 3 every time the battery cell 3 is determined bypassed. For instance, the open-circuit voltage characteristics of the bypassed battery cell 3 may be the actual nominal voltage of the battery cell 3.

In more detail, the battery management system 2 is configured to not only drive field-effect transistors of the battery system 1, such as metal-oxide-semiconductor field-effect transistors (MOSFETs), but also, if and each time a battery cell is determined to be bypassed, to obtain measurements of the actual nominal voltage and the temperature of each individual battery cell 3. Together with additional parameters, such as state of charge (SoC) and state of health (SoH), estimated by the battery management system continuously for each battery cell 3, a certain interval of the open-circuit voltage (OCV) characteristics can be directly measured whenever a battery cell 3 is bypassed and optionally after a respective relaxation time. This way, the battery management system 2 is recording already during the first full charging sequence a rudimentary OCV characteristic for each individual battery cell 3. With every further charging (or discharging) sequence, this OCV characteristic is refined by supplementary measurement intervals. And over the lifetime of a reconfigurable battery system 1, the battery management system 2 is regularly refreshing the OCV characteristics of all battery cells 3 taking their fading into account. The battery management system 2 may thus further comprise a data storage element for storing at least one of obtained measurements, determined further parameter(s) and obtained OCV characteristics of one or more battery cell 3.

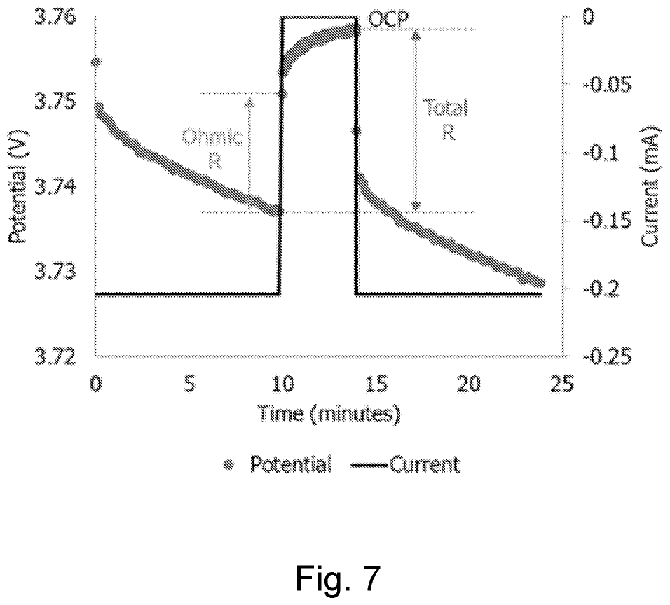

FIGS. 5 and 7 show examples of further parameters which may be determined when the battery cell 3 is bypassed. The further parameters may be determined by separate measurements and/or based on the measured actual nominal voltage and temperature of the battery cell 3.

FIG. 7 shows a plot of the potential and the current, respectively, of an electrical battery equivalent circuit diagram as a function of time. As may be seen the battery cell 3 measured upon is bypassed after 10 minutes has elapsed and is engaged again 5 minutes later, when a total of 15 minutes has elapsed. In the interval when the battery cell 3 is bypassed, the voltage response is measured. FIG. 7 illustrates how to deduce the Ohmic electrolyte resistance (Ohmic R) and the total resistance (Total R) from the voltage response due to a current interruption, i.e. bypass of the battery cell 3.

More particularly, in the moment when a battery cell 3 in the battery system 1 is changing its status from engaged to bypassed (and/or vice versa), transients in the nominal voltage of the battery cell 3 are measured by the battery management system 2 due to the sudden drop (and/or rise) in nominal current as it is illustrated in FIGS. 8A and 8B. Measuring such voltage transients at a known partial state of charge (pSoC) and current pulse, the data can be used by the battery management system 2 to approximate the value of the Ohmic electrolyte resistance and the total equivalent circuit resistance of a battery cell 3 as illustrated in FIG. 7. Gradually, this may provide the slope of the Ohmic electrolyte resistance and thus its fading for each individual battery cell 3.

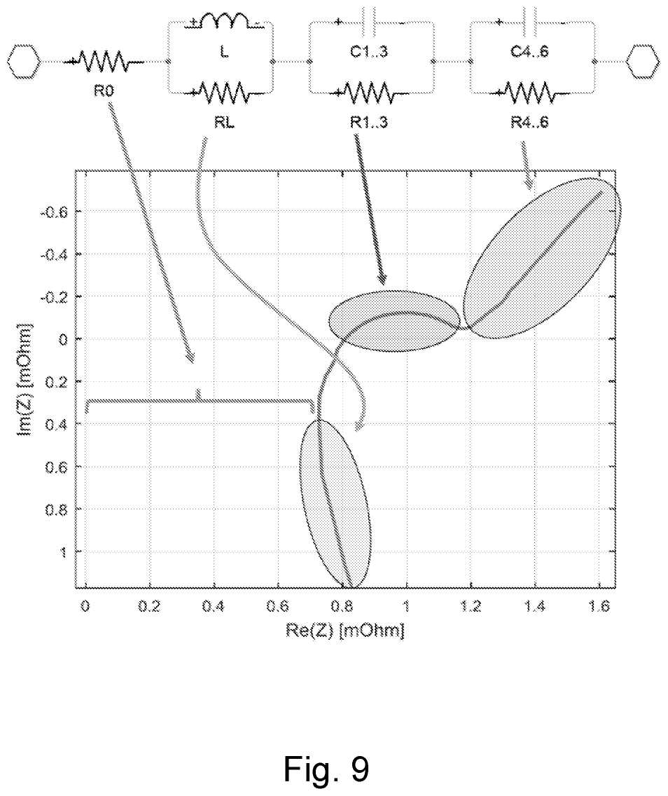

FIG. 9 shows a plot of the imaginary part of the impedance as a function of the real part of the impedance illustrating the interpretation of an electrochemical impedance spectrum (EIS) in terms of parameters in an electrical equivalent circuit diagram (EECD) of a (lithium-based) battery cell. The respective EECDs are shown at the top of FIG. 9. The measurements of the voltage response of a battery cell 3 measured to such a penetration with alternating current (AC) at a given frequency can be interpreted as a partial EIS of the battery cell 3. This partial EIS can be used to estimate and/or adjust the missing parameters for the EECD of the battery cell 3 as illustrated in FIG. 9. Whether the dedicated AC is supplied to the battery cells locally or centrally, whether this power is supplied by an additional subsystem or taken from existing subsystems (for example the control line) is optional.

More generally, the further parameters comprise, but are not necessarily limited to, characteristics such as the state of charge (SoC) of the battery cell, the partial state of charge (pSoC) of the battery cell, the state of health (SoH) of the battery cell, the current pulse, the Ohmic electrolyte resistance of the battery cell, the Warburg impedance of the battery cell and the electrochemical impedance spectrum of the battery cell.

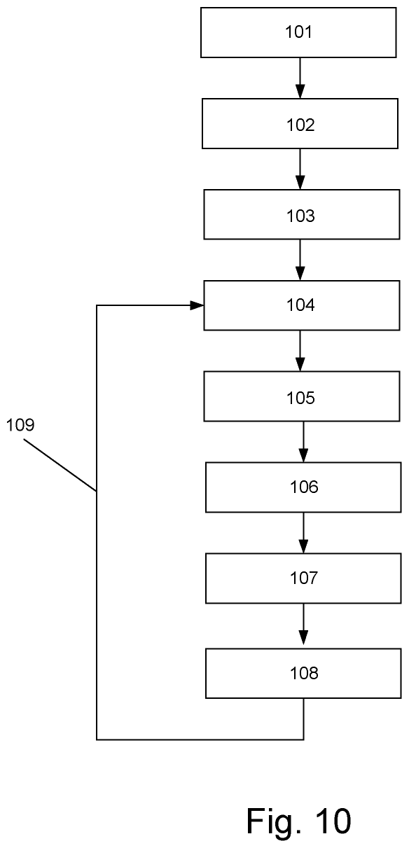

Turning now to FIG. 10, a method for in-situ controlling and monitoring individual battery cells in a battery system according to the invention is illustrated. Generally, the method comprises the following steps.

In step 101, a battery system 1 comprising a plurality of battery cells 3 and first electrical circuitry 4 is provided. The first electrical circuitry 4 is configured to enable each single battery cell 3 of the plurality of battery cells 3 to be bypassed individually.

In step 102 a battery management system 2 is provided. The battery management system 2 comprises second electrical circuitry 5.

In step 103 the battery system 1 and the battery management system 2, or more precisely the first electrical circuitry 4 and second electrical circuitry 5, is connected in such a way that for each battery cell 3 of the plurality of battery cells 3, the battery management system 2 is connected to at least a first switch 6 of the battery cell 3.

In step 104 it is determined, using the battery management system 2, whether a battery cell 3 of the plurality of battery cells 3 is bypassed, for instance by detecting transients in the nominal voltage of the battery cell 3.

If a battery cell is determined to be bypassed, the method continues to step 105 in which an actual nominal voltage and a temperature of the bypassed battery cell 3 is measured using the battery management system 2.

In step 106, one or more further parameters of the bypassed battery cell 3 is determined using the battery management system 2.

In step 107, open-circuit voltage characteristics of the bypassed battery cell 3 are determined based on the measured actual nominal voltage and temperature and the determined one or more further parameters of the bypassed battery cell 3 using the battery management system 2.

Finally, in step 108 each battery cell 3 within the battery system 1 is controlled and/or monitored based on the measured open-circuit voltage characteristics using the battery management system 2.

Step 105 of measuring open-circuit voltage characteristics of the bypassed battery cell 3, and step 106 of determining one or more further parameters of the bypassed battery cell, may further be performed after a predetermined relaxation time following determination of the battery cell 3 having been bypassed has elapsed.

The method may further comprise the optional further step of repeating step 105 of measuring open-circuit voltage characteristics of the bypassed battery cell 3 every time the battery cell 3 is determined bypassed. In practice this will involve repeating also at least step 104 to continuously monitor whether the battery cell 3 is bypassed, and if the battery cell 3 is bypassed further repeating at least step 105. Furthermore, steps 106 to 108 may also be repeated to ensure optimal monitoring and control of the battery system 1. This is illustrated by arrow 109 in FIG. 10.

Finally, step 103 may further comprise connecting the battery system 1 and the battery management system 2 in such a way that for each battery cell 3 of the plurality of battery cells 3, the battery management system 2 is connected to a first switch 6 of the battery cell 3 and to a second switch 7, and optionally at least one further switch, of the battery cell 3.

### Example

To exemplify the effect and advantages of the present invention a prototype of a battery string is considered. The prototype considered consisted of 11 battery modules with 27 battery cells 3 each. The thus 297 battery cells 3 were of lithium-iron phosphate (LFP) type and had a rated nominal capacity of 100 Ah. The operating voltage of the batteries as specified by the manufacturer was 2.5 VDC to 3.65 VDC.

Measurements with Prior Art Systems

According to the prior art, the battery management system 2 and any higher-level control system models all of the 297 battery cells with an electrical equivalent circuit diagram (EECD), and all model parameters are estimated out of prior laboratory measurements. In such a case three test runs are needed to comprehensively test a battery system, and the following measurement time would be needed.

Firstly, to measure the open-circuit voltage (OCV) characteristics of one battery takes at least 25 hours; with a counter-current measurement and 2 hours rest in between to compensate for hysteresis effects. This results in 52 hours per battery. A test run was made with facilities to perform these measurements with 5 different batteries in parallel. Altogether, this resulted in about 3.089 hours (or 129 days) of pure testing to estimate the open-circuit voltage (OCV) characteristics of the battery system.

Secondly, measurements to estimate the Ohmic electrolyte resistance takes at least 16 hours for one battery (without hysteresis compensation). Due to the higher current load needed for these measurements, only two different batteries could be tested in parallel using the prior art test systems and methods used for comparison. In sum, this added up to about 2.376 hours (or 99 days) of tests to measure the Ohmic electrolyte resistance Rs in the battery system.

Thirdly, a serious electrochemical impedance spectrum (EIS) for a battery with about 100 Ah rated nominal capacity takes about 3 hours. Since the measurement equipment needed for these measurements is expensive, typically only one battery could be tested at a time. For all 297 batteries about 891 hours (or 37 days) was required to obtain all electrochemical impedance spectra (EIS) for the whole battery system.

Assuming that large parts of the three different test runs described above are performed in parallel, the measurements for an adequate model parameter estimation would still take about 4 months for one complete battery string of the type with 297 battery cells 3 in total. Investing these 4 months of testing, however, will enable a quite accurate and precise monitoring and control of the battery system. However, over time this accuracy and precision will decrease since the batteries are degrading, and the degradation process looks different for each individual battery. Without the possibility of in-situ cell-individual measurements, the battery management system (BMS) must approximate the parameter fading of the batteries due to degradation by modelling alone. This requires sufficient computational resources and is subject to estimation errors.

If averaged model parameters are now used in the electrical equivalent circuit diagrams (EECD) the measurements may be performed for only 3 to 5 exemplary batteries. This reduces the overall test time to about 107 hours (or 5 days) at least in case parallel execution of the measurements is not feasible due to the relatively small number of batteries. Arithmetic or weighted averages of the parameters estimated from these measurements are then used model all the 297 batteries in the complete string. An advantage of this approach is that the general averaged model parameters can also be reused for other battery strings with the same type of battery cells. Nevertheless, in practice considerable deviations of these averaged model parameters from the actual (cell-individual) values are determined. The actual nominal capacity of the 297 batteries varies in a range of about 15% between 100 Ah and 115 Ah whereas the Ohmic electrolyte resistance Rₛ deviates up to 80% between 0.30 mΩ and 0.55 mΩ. This leads to a substantial error already in control of a new battery system simply by insufficient model parameter estimation. It would require quite advanced hardware of the battery management system (BMS) to compensate for this error by model-based parameter correction.

Measurements Using a System and Method According to the Invention

If now instead using the system according to the present invention, it is made possible to start with generalized averaged model parameters for each battery as in the previous paragraph or completely without any start values for the parameters in the electrical equivalent circuit diagram (EECD). Assuming that the battery string under consideration is used at a nominal system voltage of about 750 VDC, every single battery is engaged/bypassed in average about 10 times and stays bypassed at its open-circuit voltage (OCV) for about 25 minutes during each full charging or discharging cycle. This allows for the estimation of the Ohmic electrolyte resistance Rₛ for individual battery cells 3 with an error of about +/−10% already after the first full charging cycle. The OCV characteristics and the actual nominal capacity of each battery can be estimated with an error of about +/−15%. Here, these are errors for each battery and not deviations over the whole battery system. Of course, these errors are dependent of the nominal current. With higher current the estimation of the Ohmic electrolyte resistance Rₛ is more accurate while the estimation of the OCV characteristics is less accurate and vice versa. In any case, the errors in the parameter estimation becomes smaller with every charging/discharging sequence due to an extended measurement database. And this increase of accuracy and precision of the parameter estimation proceeds also over time as the batteries degrade since it is continuously kept track of the parameter fading.

With the system according to the present invention and its associated battery management system configured according to the invention, an additional dedicated power supply could be used to provide an alternating current load of, for example, 100 mA (taken from the communication line) with a fixed frequency of 1 kHz on demand to any battery cell when it is in bypassed state. The transient response in the OCV of the battery is measured and used to determine the missing parameters of the RC-circuits shown in FIG. 4 according to the relations shown in FIG. 9.

Thus, it is clear that with a system and method according to the invention the three necessary test runs may be performed considerably faster for a given number of battery cells without losing precision and accuracy in the measurements.

The person skilled in the art realizes that the present invention by no means is limited to the preferred embodiments described above. On the contrary, many modifications and variations are possible within the scope of the appended claims.

### LIST OF REFERENCE NUMERALS

1 Battery system
2 Battery management system
3 Battery cell
4 Electrical circuitry of battery system
5 Electrical circuitry of battery management system
6 Switch
7 Switch
8 Circuit element
9 Circuit element
10 Circuit element
101-109 Method steps

1. A method for controlling and monitoring individual battery cells in a battery system, such as a battery system for a charging station for electrical vehicles, the method comprising the steps of:
providing a battery system comprising a plurality of battery cells and first electrical circuitry, the first electrical circuitry being configured to enable each single battery cell of the plurality of battery cells to be bypassed individually,
providing a battery management system comprising second electrical circuitry,
connecting the first electrical circuitry and the second electrical circuitry in such a way that the battery management system is enabled to, in operation, selectively control the first electrical circuitry to bypass one or more single battery cells of the plurality of battery cells individually,
determining, using the battery management system, whether a battery cell of the plurality of battery cells is bypassed,
if a battery cell is determined to be bypassed, measuring, using the battery management system, an actual nominal voltage and a temperature of the bypassed battery cell,
determining, using the battery management system, at least one further parameter of the bypassed battery cell,
determining open-circuit voltage characteristics of the bypassed battery cell based on the measured actual nominal voltage and temperature and the determined at least one further parameter of the bypassed battery cell, and
at least one of controlling and monitoring each battery cell within the battery system based on the measured open-circuit voltage characteristics.

2. A method according to claim 1, wherein the step of connecting the first electrical circuitry and the second electrical circuitry comprises, for each battery cell of the plurality of battery cells, connecting the second electrical circuitry to a first switch of the first circuitry and associated with the battery cell.

3. A method according to claim 2, wherein the step of determining, using the battery management system, whether a battery cell of the plurality of battery cells is bypassed comprises:
detecting transients in the nominal voltage of the battery cell caused by the first switch being opened, and, if transients in the nominal voltage of the battery cell are detected, determining that the battery cell is bypassed, or
detecting whether the first switch is opened, and, if the first switch is opened, determining that the battery cell is bypassed.

4. A method according to claim 1, wherein the at least one further parameter of the bypassed battery cell comprises any one or more of a state of charge of the battery cell, a partial state of charge of the battery cell, a state of health of the battery cell, a current pulse, an Ohmic electrolyte resistance of the battery cell, a Warburg impedance and an electrochemical impedance spectrum of the battery cell.

5. A method according claim 1, wherein the step of measuring actual nominal voltage and temperature of the bypassed battery cell, and the step of determining further parameters of the bypassed battery cell, is performed after a predetermined relaxation time following determination of the battery cell having been bypassed has elapsed.

6. A method according to claim 1, wherein the step of measuring the actual nominal voltage and the temperature of the bypassed battery cell is repeated every time the battery cell is determined bypassed.

7. A method according to claim 1, wherein the step of connecting the first electrical circuitry and the second electrical circuitry comprises, for each battery cell of the plurality of battery cells, connecting the second electrical circuitry to a first switch of the first electrical circuitry and associated with the battery cell and to at least one further switch of the first electrical circuitry and associated with the battery cell.

8. A system for controlling and monitoring individual battery cells in a battery system, such as a battery system for a charging station for electrical vehicles, the system comprising:
a battery system comprising a plurality of battery cells and first electrical circuitry, the electrical circuitry being configured to enable each single battery cell of the plurality of battery cells to be bypassed individually, and
a battery management system comprising second electrical circuitry,
the first electrical circuitry and the second electrical circuitry being connected in such a way that in such a way that the battery management system is enabled to, in operation, selectively control the electrical circuitry to bypass one or more single battery cells of the plurality of battery cells individually,
the battery management system being configured to:
determine whether a battery cell of the plurality of battery cells is bypassed, and
if a battery cell is determined to be bypassed, measure an actual nominal voltage and a temperature of the bypassed battery cell,
determine at least one further parameter of the bypassed battery cell,
determine open-circuit voltage characteristics of the bypassed battery cell based on the measured actual nominal voltage and temperature and the determined at least one further parameter of the bypassed battery cell, and
at least one of controlling and monitoring each battery cell within the battery system based on the measured open-circuit voltage characteristics.

9. A system according to claim 8, wherein the battery system and the battery management system are connected in such a way that:
for each battery cell of the plurality of battery cells, the second electrical circuitry is connected to a first switch of the first electrical circuitry and associated with the battery cell, or
for each battery cell of the plurality of battery cells, the second electrical circuitry is connected to a first switch of the first electrical circuitry and associated with the battery cell and to at least one further switch of the first electrical circuitry and associated with the battery cell.

10. A system according to claim 9, wherein the battery management system further is configured to any one or more of:
determine whether a battery cell of the plurality of battery cells is bypassed by:
detecting transients in the nominal voltage of the battery cell caused by the first switch being opened, and, if transients in the nominal voltage of the battery cell are detected, determine that the battery cell is bypassed, or
detecting whether the first switch is opened, and, if the first switch is opened, determine that the battery cell is bypassed,
measure said actual nominal voltage and said temperature of the bypassed battery cell after a predetermined relaxation time following determination of the battery cell having been bypassed has elapsed, and
measure said actual nominal voltage and said temperature of the bypassed battery cell every time the battery cell is determined bypassed.
